(19) United States
(12) Patent Application Publication
(10) Pub. No.: US 2024/0079241 A1
(43) Pub. Date: Mar. 7, 2024

(54) SELECTIVE MOSI DEPOSITION

(71) Applicant: Applied Materials, Inc., Santa Clara, CA (US)

(72) Inventors: Thomas Anthony Empante, San Jose, CA (US); Avgerinos V. Gelatos, Scotts Valley, CA (US)

(73) Assignee: Applied Materials, Inc., Santa Clara, CA (US)

(21) Appl. No.: 18/238,036

(22) Filed: Aug. 25, 2023

Related U.S. Application Data
(60) Provisional application No. 63/403,407, filed on Sep. 2, 2022.

(51) Int. Cl. H01L 21/285; H01L 21/8238

(52) U.S. Cl. CPC H01L 21/28518; H01L 21/823814

(57) ABSTRACT

Methods for forming a semiconductor structure and semiconductor structures are described. Some embodiments of the method comprise patterning a substrate to form a first opening and a second opening, the substrate comprising an n transistor and a p transistor, the first opening over the n transistor and the second opening over the p transistor. The substrate is pre-cleaned. A molybdenum film is selectively deposited on the p transistor.

### CROSS-REFERENCE TO RELATED APPLICATIONS

This application claims priority to U.S. Provisional Application No. 63/403,407, filed Sep. 2, 2022, the entire disclosure of which is hereby incorporated by reference herein.

### TECHNICAL FIELD

Embodiments of the present disclosure pertain to the field of semiconductor devices and semiconductor device manufacturing. More particularly, embodiments of the disclosure relate to methods of selectively forming silicide layers.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (finFET) structure, and a gate all around (GAA) structure. Logic gate performance is related to the characteristics of the materials used as well as the thickness and area of the structural layers. However, as some gate characteristics are adjusted to accommodate device scaling, challenges arise.

Current dual silicide techniques require multiple steps to mask the nMOS junction before the pMOS silicide can be deposited. These process flows cause longer, more complex processes which greatly effects throughput. Therefore, there is a need for a simplified dual silicide process flow including the selective silicidation of the pMOS junction without the need for masking and unmasking the nMOS junction.

### SUMMARY

One or more embodiments of the disclosure are directed to a method of selectively depositing a molybdenum film. The method comprises exposing a substrate surface comprising a first material and a second material to a preclean process and forming a residue on the substrate surface. The first material consists essentially of silicon, and the second material consists essentially of silicon germanium (SiGe). The substrate surface is exposed to a molybdenum precursor and a reductant to selectively form the molybdenum film on the second material over the first material.

Another embodiment of the disclosure is directed to a method of selectively depositing a molybdenum silicide film. The method comprises exposing a substrate surface comprising a first material and a second material to a cleaning agent. The first material consists essentially of silicon, and the second material consists essentially of silicon germanium (SiGe). The cleaning agent comprises a plasma of ammonia and NF₃, and exposure to the cleaning agent selectively forms a residue on the first material. The substrate is dechucked by exposing the substrate to an Ar plasma, and then sequentially exposed to a molybdenum precursor and a silane precursor to selectively form the molybdenum silicide film on the second material over the first material. The substrate surface is maintained at a temperature in a range of 300° C. to 325° C.

Further embodiments of the disclosure are directed to a method of selectively depositing a molybdenum silicide film. The method comprises exposing a substrate surface comprising an n transistor and a p transistor to a cleaning agent. The source drain material of the n transistor consists essentially of silicon, and the source/drain material of the p transistor consists essentially of silicon germanium (SiGe). The cleaning agent comprises a plasma of ammonia and NF₃, and exposure to the cleaning agent selectively forms a residue of ammonium silicate on the source/drain material of the n transistor. The substrate is dechucked by exposing the substrate to an Ar plasma, and then sequentially exposed to a molybdenum precursor and a silane precursor to selectively form the molybdenum silicide film on the source/drain material of the p transistor over the source/drain material of the n transistor. The substrate surface is maintained at a temperature in a range of 300° C. to 325° C.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method according to one or more embodiments;

FIG. 2 illustrates a semiconductor structure in accordance with one or more embodiments of the disclosure; and

FIG. 3 illustrates a semiconductor structure in accordance with one or more embodiments of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As use herein, the term “substrate,” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

Additionally, the term “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, dielectric materials, other conductive materials, or combinations thereof, depending on the application. In some embodiments, the substrate comprises silicon (Si), ruthenium (Ru), cobalt (Co), tungsten (W), molybdenum (Mo), silicon phosphide (SiP), titanium silicon (TiSi), titanium nitride (TiN), titanium aluminide (TiAl), silicon germanium (SiGe), silicon germanium boron (SiGeB), hafnium oxide (HfO₂), aluminum oxide (Al₂O₃) or combinations thereof. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top, two sidewalls and a bottom, peaks which have a top and two sidewalls extending upward from a surface, and vias which have sidewalls extending down from a surface with an open bottom.

As used herein, the term “processing chamber” includes portions of a processing chamber adjacent the substrate surface without encompassing the complete interior volume of the processing chamber. For example, in a sector of a spatially separated processing chamber, the portion of the processing chamber adjacent the substrate surface is purged of one or more reactive compounds by any suitable technique including, but not limited to, moving the substrate through a gas curtain to a portion or sector of the processing chamber that contains none or substantially none of the reactive compounds.

As used herein, the term “atomic layer deposition” or “cyclical deposition” refers to the sequential exposure of two or more reactive compounds to deposit a layer of material on a substrate surface. The substrate, or portion of the substrate surface is exposed sequentially to the two or more reactive compounds which are introduced into a reaction zone of a processing chamber. The sequential exposure of the reactive gases prevents or minimizes gas phase reactions between the reactive gases. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In one or more embodiments, the time-domain ALD process can be performed with more than two reactive compounds in a predetermined sequence.

In an aspect of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. In one or more embodiments, the spatial ALD process can be performed with more than two reactive compounds in a predetermined sequence.

In some embodiments, the substrate surface is exposed to the first reactive compound and the second reactive compound substantially sequentially. As used herein throughout the specification, “substantially sequentially” means that most of the duration of the first reactive compound exposure does not overlap with the second reactive compound exposure, although there may be some overlap.

As used herein, the term “chemical vapor deposition” refers to the exposure of at least one reactive compound to deposit a layer of material on the substrate surface. In some embodiments, the chemical vapor deposition (CVD) process comprises mixing the two or more reactive compounds in the processing chamber to allow gas phase reactions of the reactive compounds and deposition. In some embodiments, the CVD process comprises exposing the substrate surface to two or more reactive compounds simultaneously. In some embodiments, the CVD process comprises exposing the substrate surface to a first reactive compound continuously with an intermittent exposure to a second reactive compound. In some embodiments, the substrate surface undergoes the CVD reaction to deposit a film having a predetermined thickness. In the CVD process, the film can be deposited in one exposure to the mixed reactive compounds or can be multiple exposures to the mixed reactive compounds with purges between. In some embodiments, the substrate surface is exposed to the first reactive compound and the second reactive compound substantially simultaneously.

As used herein throughout the specification, “substantially simultaneously” means that most of the duration of the first reactive compound exposure overlaps with the second reactive compound exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive compound is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive compound.

As used herein, the terms “liner” or “barrier layer” refer to a layer conformably formed along at least a portion of the sidewalls and/or lower surface of an opening such that a substantial portion of the opening prior to the deposition of the layer remains unfilled after deposition of the layer. The liner may be formed along the entirety of the sidewalls and lower surface of the opening. The liner can be formed by any process known to a person skilled in the art. In some embodiments, the liner comprises a metal nitride, a PVD metal or combinations thereof. In one or more embodiments, the “liner” or “barrier layer” can also be formed selectively at the bottom of the structure.

Transistors are circuit components or elements that are often formed on semiconductor devices. Many transistors may be formed on a semiconductor device in addition to capacitors, inductors, resistors, diodes, conductive lines, or other elements, depending upon the circuit design. The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals.

Generally, a transistor includes a gate formed between source and drain regions. The source and drain regions may include a doped region of a substrate and may exhibit a doping profile suitable for a particular application. The gate is positioned over the channel region and may include a gate dielectric interposed between a gate electrode and the channel region in the substrate.

As used herein, the term “field effect transistor” or “FET” refers to a transistor that uses an electric field to control the electrical behavior of the device. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both be of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

Embodiments of the disclosure provide semiconductor structures and methods for forming a semiconductor structure. Typical dual silicide flows, however, are very complex, requiring separate opening of contacts to n+ and p+ junctions, doubling lithography and etching steps. Accordingly, one or more embodiments advantageously provide integration schemes to produce dual silicides on the pFET contact. In one or more embodiments, selective molybdenum silicide (MoSi) growth is used to simplify current process complexity.

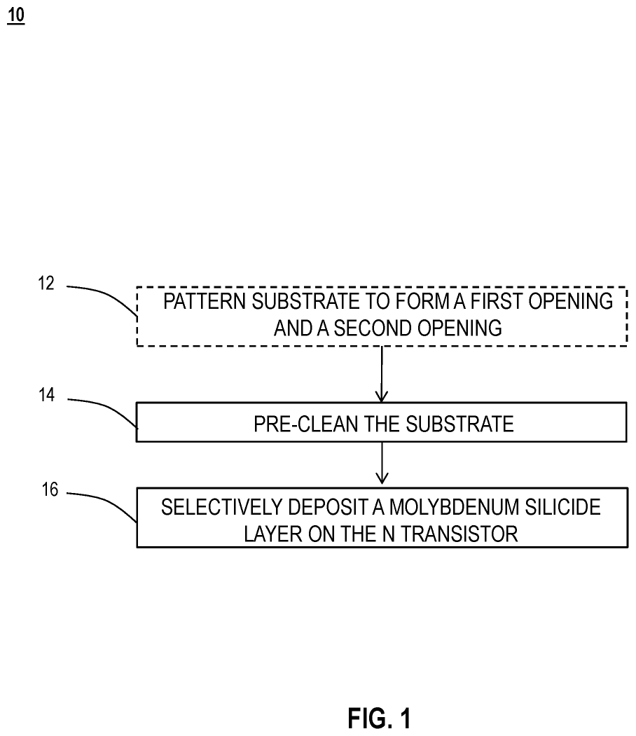

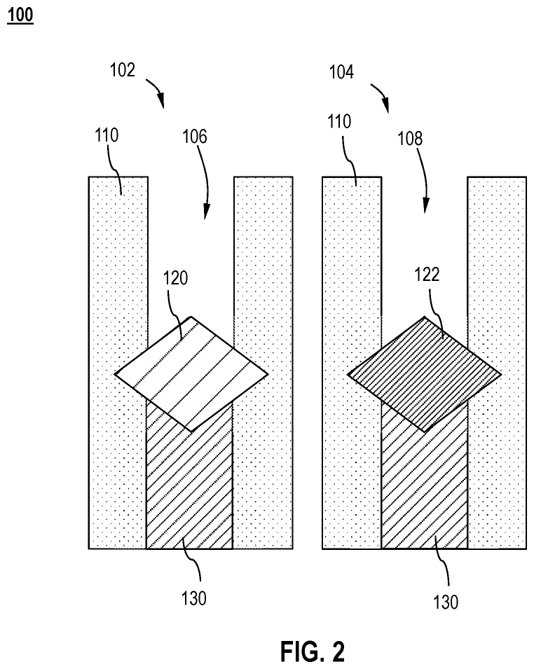

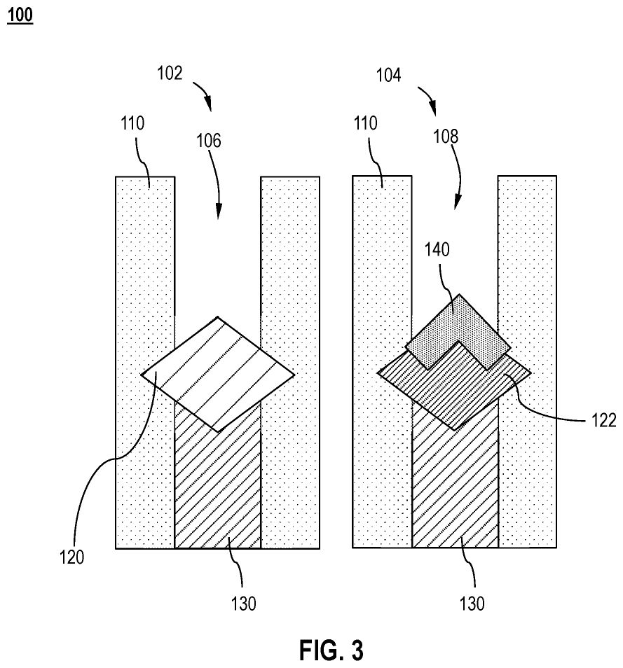

The embodiments of the disclosure are described by way of the Figures, which illustrate processes for forming dual silicides on the pFET contact. FIG. 1 illustrates a process flow diagram of a method 10 of forming a semiconductor structure 100. FIG. 1 illustrates a method of forming any of the semiconductor structures of one or more embodiments shown in FIGS. 2-3.

In this regard, the term “semiconductor structure” does not only refer to a structure completed according to the disclosed methods, but also intermediate structures during processing by the disclosed methods. The semiconductor structure 100 may also be simply referred to as a substrate with an exposed substrate surface. In this regard, while the methods disclosed herein are discussed as acting on a disclosed semiconductor structure, the methods may equally apply to other substrates or structures. In an effort to generally describe the process, the source/drain material 120 of the n transistor 102 may be referred to as a first material, while the source/drain material of the p transistor 104 may be referred to as a second material.

In one or more embodiments, the method 10 of forming a semiconductor structure comprises, at operation 12, patterning a substrate to form a first opening and a second opening, the substrate comprising an n transistor and a p transistor, the first opening over the n transistor and the second opening over the p transistor. At operation 14, the method 10 comprises pre-cleaning the substrate. At operation 16, the method 10 comprises selectively depositing a molybdenum silicide (MoSi) layer on the p transistor.

With reference to FIGS. 1 and 2-3, in some embodiments, the method, at operation 12, comprises patterning a substrate 100 to form at least one of a first opening 106 and a second opening 108. In one or more embodiments, patterning the substrate comprises using one or more patterning techniques known to one of ordinary skill in the art of microelectronic device manufacturing. In some embodiments, the semiconductor structure 100 is provided with a first opening 106 and a second opening 108 such that no patterning to form the semiconductor structure 100 is required.

With reference to FIGS. 2-4, a semiconductor structure 100 is shown. The semiconductor structure 100 comprises an n transistor 102 and a p transistor 104. In one or more embodiments, each of the n transistor 102 and the p transistor 104 comprise a dielectric material 110, a source/drain material 120, 122, and a base material 130.

In one or more embodiments, the dielectric material 110 may comprise any suitable dielectric material known to the skilled artisan. As used herein, the term “dielectric material” refers to an electrical insulator that can be polarized in an electric field. In some embodiments, the dielectric material 110 comprises one or more of silicon, silicon oxide, silicon nitride, silicon carbide, and low-K dielectrics. As used herein, terms such as “silicon oxide” and “silicon nitride” refer to materials comprising silicon and oxygen or silicon and nitrogen. “Silicon oxide” and “silicon nitride” should not be understood to imply any stoichiometric ratio. Stated differently, a dielectric material comprising silicon oxide or silicon nitride may be stoichiometric or non-stoichiometric, silicon-rich, or silicon-poor. In some embodiments, the dielectric material 110 comprises silicon oxide (SiO₂).

In some embodiments, the n transistor 102 and the p transistor 104 comprise source and drain contacts. In one or more embodiments, the source/drain material 120, 122 may have more than one layer.

In one or more specific embodiments, the source/drain material 120 of the n transistor 102 comprises silicon (Si). The source/drain 120 material of the n transistor 102 may be doped or undoped. In one or more embodiments, the source/drain material 120 of the n transistor 102 comprises or consists essentially of silicon (Si). In some embodiments, the source/drain material 120 of the n transistor 102 comprises amorphous silicon.

In one or more embodiments, the source/drain material 122 of the p transistor 104 comprises silicon germanium (SiGe). In one or more embodiments, the silicon germanium (Ge) may have any suitable concentration of germanium. In some embodiments, the silicon germanium (SiGe) has a concentration of germanium in a range of from 10% to 100%, or in a range of from 20% to 60%. The source/drain 122 material of the p transistor 104 may be doped or undoped. In one or more embodiments, the source/drain material 122 of the p transistor 104 consists essentially of undoped silicon germanium (SiGe).

Referring to FIGS. 2-3, in one or more embodiments, there is a first opening 106 over the n transistor 102, and there is a second opening 108 over the p transistor 104. The first opening 106 and the second opening 108 can have any suitable aspect ratio (ratio of the depth of the opening to the width of the opening). In one or more embodiments, the first opening 106 and the second opening 108 may independently have an aspect ratio in a range of from 3:1 to 15:1, or in a range of from 6:1 to 15:1, or in a range of from 9:1 to 15:1, or in a range a range of from 12:1 to 15:1. In one or more embodiments, the first opening 106 and the second opening 108 may independently have an aspect ratio greater than 10:1.

In one or more embodiments, at operation 14, the method comprises pre-cleaning the substrate. In one or more embodiments, keeping the pre-cleaning process under vacuum ensures that no oxide is introduced/formed on the substrate surface after pre-cleaning the substrate. In some embodiments, pre-cleaning the substrate (or surface of the substrate) removes oxides from the surface. In some embodiments, the oxides are native oxides. In some embodiments, cleaning the surface forms a surface that is substantially free of oxides. As used in this manner, the term “substantially free of oxides” means that there are less than or equal to 5%, 2%, 1% or 0.5% of oxygen atoms on the surface. In one or more embodiments, pre-cleaning the surface forms a source/drain material that is substantially free of oxide.

In some embodiments, the pre-cleaning process comprises exposing the substrate surface to a cleaning agent comprising ammonia. In some embodiments, the cleaning agent further comprises NF₃ or HF. In some embodiments, the cleaning agent consist essentially of ammonia and NF₃. In some embodiments, the cleaning agent consist essentially of ammonia and HF. In some embodiments, the cleaning agent is ignited to form a cleaning plasma.

In some embodiments, the pre-cleaning process forms a residue on the source/drain materials 120, 122. In some embodiments, the residue is formed on the source/drain material 120 of the p transistor 104. In some embodiments, the residue is formed on the source/drain material 122 of the n transistor 102. In some embodiments, the residue is selectively formed on the source/drain material 120. In some embodiments, the residue comprises ammonium silicate.

In some embodiments, after exposing the substrate surface to the preclean process, the method further comprises dechucking the substrate. In some embodiments, dechucking the substrate comprises exposing the substrate to an Ar plasma. In some embodiments, dechucking the substrate comprises exposing the substrate to a plasma which does not contain substantially any ammonia.

Without being bound by theory, it is believed that in some embodiments, the residue remaining of the substrate surfaces impairs the ability of the molybdenum precursor and the reductant to react to form the molybdenum film on the substrate.

With reference to FIG. 1 and FIG. 3, at operation 16, a molybdenum film 140 is selectively deposited on the p transistor 104 source/drain 122. As used in this regard, a molybdenum film is any film comprising molybdenum. In some embodiments, the molybdenum film consists essentially of molybdenum. In some embodiments, the molybdenum film comprises or consists essentially of molybdenum silicide (MoSi).

In one or more embodiments, it was advantageously found that molybdenum grows preferentially on silicon germanium (SiGe) versus silicon (Si), allowing for an integration flow which does not increase the number of lithography and etch steps. In one or more embodiments, the molybdenum film is selectively formed on the silicon germanium (SiGe) source/drain 122 of the p transistor and not on the silicon source/drain 120 of the n-transistor.

In one or more embodiments, the molybdenum film 140 may be formed by any suitable means. In one or more embodiments, the molybdenum film 140 is formed on the p transistor by exposing the substrate surface to a molybdenum precursor and a reductant.

In some embodiments, the molybdenum precursor comprises or consists essentially of a molybdenum halide. In some embodiments, the molybdenum precursor comprises or consists essentially of MoCl₅.

In some embodiments, the reductant comprises a silane precursor and the molybdenum film comprises molybdenum silicide. In some embodiments, the silane precursor is selected from one or more silane, disilane, trisilane, or other higher order silanes. In some embodiments, the silane precursor consists essentially of silane.

In some embodiments, the reductant comprises H₂ and the molybdenum film consists essentially of molybdenum. In some embodiments, after forming a molybdenum film consisting essentially of molybdenum, the molybdenum film is exposed to a sail precursor to form a molybdenum silicide film.

In some embodiments, the substrate surface is exposed to the molybdenum precursor and the reductant simultaneously. In some embodiments, the molybdenum precursor is pulsed into a constant flow of the reductant.

In some embodiments, the substrate surface is exposed to the molybdenum precursor and the reductant sequentially. In some embodiments, the molybdenum film is formed by a time-based ALD process with intervening purges of the substrate surface. In some embodiments, the molybdenum film is formed by a spatial ALD process.

In one or more embodiments, the molybdenum film 140 is selectively deposited on the source/drain material 122 of the p-transistor and not on the source/drain material 120 of the n-transistor. As used in this specification and the appended claims, the term “selectively depositing a film on one surface over another surface”, and the like, means that a first amount of the film is deposited on the first surface and a second amount of film is deposited on the second surface, where the second amount of film is less than the first amount of film, or no film is deposited on the second surface.

The selectivity of a deposition process is generally expressed as a multiple of growth rate. For example, if one surface is grown (or deposited on) twenty-five times faster than a different surface, the process would be described as having a selectivity of 25:1 or simply 25. In this regard, higher ratios indicate more selective processes.

In some embodiments, the molybdenum film is formed with a selectivity of greater than or equal to 5, greater than or equal to 10, greater than or equal to 15, greater than or equal to 20, or greater than or equal to 25.

In some embodiments, the method 10 is able to achieve selective deposition without masking or blocking the source/drain material 120 of the n transistor 102. Without being bound by theory, the disclosed methods are able to form a molybdenum film and more quickly further process the substrate because the methods do not rely on masking and unmasking the various surfaces between deposition processes. Accordingly, the disclosed methods relate to shorter process flows and enable higher throughput.

The temperature of the substrate during exposure to the ruthenium precursor can be controlled, for example, by setting the temperature of the substrate support or susceptor. This temperature is also referred to as the deposition temperature. In some embodiments the substrate is held at a temperature in the range of about 300° C. to about 325° C., or in the range of about 300° C. to about 315° C., or in the range of about 310° C. to about 325° C. The inventors have surprisingly found that the disclosed methods demonstrate a narrow range of selectivity. At temperatures above or below the disclosed ranges, the disclosed methods demonstrate less or even no selectivity between the first material and the second material.

In some embodiments, the deposition process is performed as a thermal process without the use of plasma reactants. Stated differently, the method is performed without plasma.

In some embodiments, the thickness of the molybdenum film on the second material is greater than or equal to about 40 Å, greater than or equal to about 60 Å or greater than or equal to about 75 Å. In some embodiments, the selectivity of the disclosed methods deposits less than 10 Å, less than 5 Å, or less than 3 Å of the molybdenum film on the first material.

Several well-known cluster tools which may be adapted for the present disclosure are the Endura®, the Olympia®, the Continuum®, and the Trillium®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), plasma treatment, etch, pre-clean, chemical clean, thermal treatment such as RTP, plasma nitridation, degas, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of selectively depositing a molybdenum film, the method comprising:
exposing a substrate surface comprising a first material and a second material to a preclean process and forming a residue on the substrate surface, the first material consisting essentially of amorphous silicon, the second material consisting essentially of silicon germanium (SiGe); and
exposing the substrate surface to a molybdenum precursor and a reductant to selectively form the molybdenum film on the second material over the first material.

2. The method of claim 1, wherein the preclean process comprises exposing the substrate surface to a cleaning agent comprising ammonia or NF₃.

3. The method of claim 2, wherein the cleaning agent consists essentially of ammonia and NF₃.

4. The method of claim 2, wherein the cleaning agent is ignited to form a cleaning plasma.

5. The method of claim 2, wherein the residue comprises ammonium silicate.

6. The method of claim 2, wherein the residue is selectively formed on the first material.

7. The method of claim 2, further comprising dechucking the substrate after precleaning.

8. The method of claim 7, wherein dechucking the substrate comprises exposing the substrate to an Ar plasma.

9. The method of claim 1, wherein the molybdenum precursor consists essentially of MoCl₅.

10. The method of claim 1, wherein the reductant comprises a silane precursor.

11. The method of claim 1, wherein the reductant comprises H₂ and the method further comprises exposing the molybdenum film to a silane precursor to form a molybdenum silicide film.

12. The method of claim 1, wherein the substrate surface is exposed to the molybdenum precursor and the reductant simultaneously.

13. The method of claim 11, wherein the molybdenum precursor is pulsed into a constant flow of the reductant.

14. The method of claim 1, wherein the substrate surface is exposed to the molybdenum precursor and the reductant sequentially.

15. The method of claim 1, wherein the molybdenum film is formed with a selectivity greater than or equal to about 20.

16. The method of claim 1, wherein the molybdenum film is selectively formed on the second material without masking or blocking the first material.

17. The method of claim 1, wherein the substrate is maintained at a temperature in a range of 300° C. to 325° C.

18. The method of claim 1, wherein the first material comprises the source/drain material of an n transistor and the second material comprises the source/drain material of a p transistor.

19. A method of selectively depositing a molybdenum silicide film, the method comprising:
exposing a substrate surface comprising a first material and a second material to a cleaning agent, the first material consisting essentially of amorphous silicon, the second material consisting essentially of silicon germanium (SiGe), the cleaning agent comprising a plasma of ammonia and NF₃, exposure to the cleaning agent selectively forming a residue on the first material;
dechucking the substrate by exposing the substrate to an Ar plasma; and
sequentially exposing the substrate surface to a molybdenum precursor and a silane precursor to selectively form the molybdenum silicide film on the second material over the first material, the substrate surface maintained at a temperature in a range of 300° C. to 325° C.

20. A method of selectively depositing a molybdenum silicide film, the method comprising:
exposing a substrate surface comprising an n transistor and a p transistor to a cleaning agent, the source/drain material of the n transistor consisting essentially of amorphous silicon, the source/drain material of the p transistor consisting essentially of silicon germanium (SiGe), the cleaning agent comprising a plasma of ammonia and NF₃, exposure to the cleaning agent selectively forming a residue of ammonium silicate on the source/drain material of the n transistor;
dechucking the substrate by exposing the substrate to an Ar plasma; and
sequentially exposing the substrate surface to a molybdenum precursor and a silane precursor to selectively form the molybdenum silicide film on the source/drain material of the p transistor over the source/drain material of the n transistor, the substrate surface maintained at a temperature in a range of 300° C. to 325° C.
